(19) United States
(12) Patent Application Publication
(10) Pub. No.: US 2025/0048798 A1
(43) Pub. Date: Feb. 6, 2025

(54) LIGHT EMITTING ELEMENT

(71) Applicant: TOYODA GOSEI CO., LTD., Kiyosu-shi, Aichi-ken (JP)

(72) Inventors: Hiroaki MAKINO, Kiyosu-shi (JP); Hideki OMOYA, Kiyosu-shi (JP); Koji OKUNO, Kiyosu-shi (JP)

(21) Appl. No.: 18/788,907

(22) Filed: Jul. 30, 2024

(30) Foreign Application Priority Data
Aug. 2, 2023 (JP) 2023-126475

(51) Int. Cl. H01L 33/40; H01L 33/00; H01L 33/32; H01L 33/38

(52) U.S. Cl. CPC H01L 33/405; H01L 33/0075; H01L 33/325; H01L 33/38; H01L 2933/0016

(57) ABSTRACT

A flip-chip type light emitting element of ultraviolet light emission includes: a p-type layer containing a p-type group III nitride semiconductor, and a p-side electrode serving as a reflective electrode provided over the p-type layer, and the p-side electrode contains Mg or an alloy containing Mg as a main component and is in contact with the p-type layer.

### CROSS-REFERENCE TO RELATED APPLICATION

This application is based on and claims priority under 35 USC 119 from Japanese Patent Application No. 2023-126475 filed on Aug. 2, 2023.

### TECHNICAL FIELD

The present invention relates to a light emitting element.

### BACKGROUND ART

A wavelength of ultraviolet light from a solid-state light emitting element using a Group III nitride semiconductor corresponds to a wavelength band in a range of about 210 nm to 400 nm. It is known that UVC (having a wavelength of 100 nm to 280 nm) can be efficiently used in sterilization and removing bacteria, and usage of the UVC for sterilizing and disinfecting water, air, and the like is attracting attention. Therefore, there is an increasing demand for a Group III nitride semiconductor light emitting element that emits ultraviolet light having an emission wavelength corresponding to UVC, and research and development are being actively conducted to improve efficiency.

An ultraviolet light emitting element using a Group III nitride semiconductor employs a flip-chip type in which light is extracted from a back surface of a substrate. In such a flip-chip type, it is possible to improve light extraction efficiency by increasing reflectivity of a p-side electrode and causing the p-side electrode to reflect ultraviolet light to a light extraction side.

JP2019-36629A discloses a structure in which a Ni layer and a Mg layer are stacked in order from a p-type layer side as a p-side electrode of an ultraviolet light emitting element using a Group III nitride semiconductor. The Ni layer is a layer for achieving good contact with the p-type layer, and the Mg layer is a layer for reflecting ultraviolet light in the UVC band. In the UVC band, Mg has higher reflectivity than Al. In JP2019-36629A, Mg is used as a reflective layer of the p-side electrode to increase reflectivity.

JP2014-96539A discloses a Group III nitride semiconductor light emitting element having an emission wavelength of 300 nm or less, and discloses that a transparent electrode made of Mg is used as a positive electrode that is in contact with a p-type layer.

### SUMMARY OF INVENTION

However, external quantum efficiency EQE of Ni/Mg disclosed in JP2019-36629A may be lower than that of Ni/Al. In the case of Ni/Mg, optimization is required to achieve both an increase in reflectivity and a reduction in contact resistance, but in order to achieve such optimization, it is required to optimize a thickness of the Ni layer or an annealing condition, which is considered to be difficult.

JP2014-96539A discloses that Mg is used as the transparent electrode by thinning Mg and Mg is used as a reflective electrode.

The present invention has been made in view of such a background, and an object of the present invention to provide a light emitting element including a p-side electrode having high reflectivity.

An aspect of the present invention is directed to a flip-chip type light emitting element of ultraviolet light emission, the light emitting element comprising:
a p-type layer comprising a p-type group III nitride semiconductor; and
a p-side electrode serving as a reflective electrode provided over the p-type layer, wherein
the p-side electrode comprises Mg or an alloy containing Mg as a main component and is in contact with the p-type layer.

Another aspect of the present invention is directed to a manufacturing method of a flip-chip type light emitting element of ultraviolet light emission, the light emitting element including a p-type layer containing a p-type group III nitride semiconductor and a p-side electrode serving as a reflective electrode provided over the p-type layer, the manufacturing method comprising:
forming the p-side electrode so that the p-side electrode is provided on and is in contact with the p-type layer and contains Mg or an alloy containing Mg as a main component; and
performing annealing in an inert gas atmosphere at a temperature of 150° C. or more and 400° C. or less for 30 seconds or more and 12 minutes or less after the forming of the p-side electrode.

According to the above aspects, the p-side electrode is made of Mg or an alloy containing Mg as a main component, and is in direct contact with the p-type layer. Therefore, it is possible to implement a p-side electrode having high reflectivity in the UVC band while maintaining good contact with the p-type layer.

### BRIEF DESCRIPTION OF DRAWINGS

FIG. 1 is a cross-sectional view showing a configuration of a light emitting element according to Embodiment 1 and showing a cross section in a direction perpendicular to a main surface of a substrate.

FIGS. 2A, 2B and 2C are views showing a manufacturing configuration of the light emitting element according to Embodiment 1.

FIG. 3 is a graph showing a relationship between a thickness of a Mg layer and relative reflectivity.

FIG. 4 is a graph showing current dependence of light outputs Po of light emitting elements according to Example 1 and Comparative Examples 1 and 2.

FIG. 5 is a graph showing current dependence of external quantum efficiency EQE of the light emitting elements according to Example 1 and Comparative Examples 1 and 2.

FIG. 6 is a graph showing I-V features of the light emitting elements according to Example 1 and Comparative Examples 1 and 2.

FIG. 7 is a graph showing power conversion efficiency WPE of the light emitting elements according to Example 1 and Comparative Examples 1 and 2.

FIG. 8 is a graph showing a relationship between a wavelength of ultraviolet light and relative reflectivity.

FIGS. 9A, 9B and 9C are views showing micrographs of a p-side electrode.

FIG. 10 is a graph showing I-V features before and after annealing.

FIG. 11 is a graph showing emission spectra before and after annealing.

FIG. 12 is a graph showing a change over time in an annealing temperature.

FIG. 13 is a graph showing a relationship between an annealing temperature and a Vf reduction amount.

FIG. 14 is a graph showing a relationship between an annealing temperature and a reflectivity change amount of Mg/Ti.

FIG. 15 is a graph showing a change over time in an annealing temperature.

FIG. 16 is a graph showing a relationship between an annealing time and a Vf reduction amount.

FIG. 17 is a graph showing a relationship between an annealing time and a reflectivity change amount of Mg/Ti.

FIG. 18 is a graph showing a relationship between a light output Po and a current of the light emitting element according to Example 1.

FIG. 19 is a graph showing I-V features of the light emitting element according to Example 1.

### DETAILED DESCRIPTION OF THE INVENTION

A flip-chip type light emitting element of ultraviolet light emission includes a p-type layer made of a p-type group III nitride semiconductor, and a p-side electrode serving as a reflective electrode provided on the p-type layer, in which the p-side electrode is made of Mg or an alloy containing Mg as a main component and is in contact with the p-type layer.

A thickness of the p-side electrode may be set such that reflectivity at an emission wavelength is 50% or more.

The thickness of the p-side electrode may be 40 nm or more. Further, the thickness of the p-side electrode may be 80 nm or more.

The light emitting element may further include a protective layer that is provided on the p-side electrode in a contact manner and is made of Ti, TiN, or Ni.

An emission wavelength of the light emitting element may be 210 nm to 280 nm.

A manufacturing method of a light emitting element of ultraviolet light emission is a manufacturing method of a flip-chip type light emitting element of ultraviolet light emission, the light emitting element includes a p-type layer made of a p-type group III nitride semiconductor and a p-side electrode serving as a reflective electrode provided on the p-type layer, the manufacturing method includes a p-side electrode forming step of forming the p-side electrode that is provided on the p-type layer in a contact manner and is made of Mg or an alloy containing Mg as a main component, and an annealing step of performing annealing in an inert gas atmosphere at a temperature of 150° C. or more and 400° C. or less for 30 seconds or more and 12 minutes or less after the p-side electrode is formed.

An annealing temperature of the annealing step may be 200° C. or more and 350° C. or less. An annealing time of the annealing step may be 2 minutes or more and 8 minutes or less.

In the p-side electrode forming step, a thickness of the p-side electrode may be 40 nm or more. Further, in the p-side electrode forming step, the thickness of the p-side electrode may be 80 nm or more.

The p-side electrode forming step may include a step of forming a protective layer that is provided on the p-side electrode in a contact manner and is made of Ti, TiN, or Ni.

In the manufacturing method of the light emitting element, an emission wavelength of the light emitting element may be 210 nm to 280 nm.

### Embodiment 1

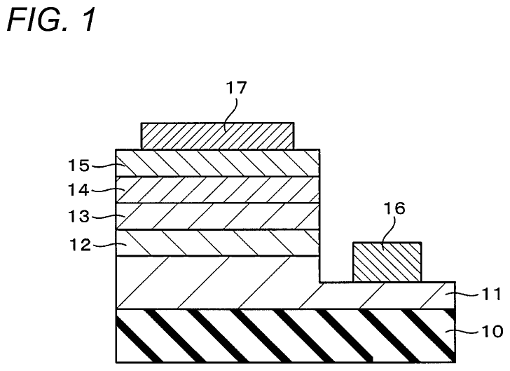

FIG. 1 is a cross-sectional view showing a configuration of a light emitting element according to Embodiment 1 and showing a cross section in a direction perpendicular to a main surface of a substrate. As shown in FIG. 1, the light emitting element according to Embodiment 1 includes a substrate 10, an n-type layer 11, an active layer 12, an electron blocking layer 13, a composition graded layer 14, a p-type contact layer 15, an n-side electrode 16, and a p-side electrode 17. The light emitting element according to Embodiment 1 is of a flip-chip type in which light is extracted from a back surface (a surface opposite to the n-type layer 11) of the substrate 10. An emission wavelength is a predetermined wavelength in a range of 210 nm to 280 nm, and is in a UVC band (100 nm to 280 nm).

### 1. Configuration of Light Emitting Element

A configuration of each layer of the light emitting element according to Embodiment 1 will be described in detail.

The substrate 10 is a substrate made of sapphire having a c-plane as a main surface. A plane orientation of the main surface of sapphire may be an a-plane. The plane orientation may have an off angle of 0.1 to 2 degrees in an m-axis direction. A back surface (a surface opposite to the n-type layer 11) of the substrate 10 is a main surface for extracting light. An antireflection film may be provided on the back surface of the substrate 10 to improve a light extraction rate. A surface of the substrate 10 may be provided with irregularities to improve a light extraction rate. An AlN substrate or an AlN template substrate in which an AlN layer is formed on a sapphire substrate may be used as the substrate 10.

A thickness of the substrate 10 is, for example, 1000 μm or less. The thickness of the substrate 10 is preferably 300 μm or more and 500 μm or less. Light extraction from a side surface of the substrate 10 can be prevented, and an axial intensity can be improved.

The substrate 10 may be removed by a method such as laser lift off (LLO).

The n-type layer 11 is located on the substrate 10. The n-type layer 11 is made of n-AlGaN. An Al composition (a molar ratio of Al in all group III metals) is, for example, 60% to 90%. An n-type impurity is Si, and a Si concentration is, for example, 1×10¹⁸ cm⁻³ to 5×10¹⁹ cm⁻³. A thickness of the n-type layer 11 is, for example, 0.5 μm to 5 μm. A C concentration of the n-type layer 11 is 1×10¹⁵ cm⁻³ to 1×10¹⁹ cm⁻³. The n-type layer 11 may include a plurality of layers. For example, the n-type layer 11 may be a superlattice layer in which AlGaN having different Al compositions are alternately stacked. Further, a base layer made of AlN may be provided between the substrate 10 and the n-type layer 11. In addition, materials other than Si may be used as the n-type impurity.

The active layer 12 is located on the n-type layer 11. The active layer 12 has an SQW structure in which a barrier layer, a well layer, and a barrier layer are stacked in this order from the n-type layer 11 side. The active layer 12 may have an MQW structure. In this case, the number of repetitions is, for example, 2 to 10.

The well layer is made of AlGaN, and an Al composition thereof is set according to a desired emission wavelength. A Si concentration of the well layer is, for example, 1×10¹⁸ cm⁻³ or less, and may be non-doped. A thickness of the well layer is, for example, 0.5 nm to 5 nm.

The barrier layer is made of AlGaN having an Al composition higher than that of the well layer, and the Al composition is, for example, 50% to 100%. A Si concentration of the barrier layer is, for example, 2×10¹⁹ cm⁻³ or less, and may be non-doped. A thickness of the barrier layer is, for example, 3 nm to 30 nm. The barrier layer may be AlGaInN having band gap energy larger than that of the well layer. Among barrier layers, a layer in contact with the electron blocking layer 13 preferably has a thickness of 0.5 nm to 10 nm.

A hole blocking layer may be provided between the n-type layer 11 and the active layer 12. Holes injected from the p-side electrode 17 can be prevented from going beyond the active layer 12 and diffusing toward the n-type layer 11 side. The hole blocking layer is AlGaN or AIN having an Al composition higher than that of the barrier layer of the active layer 12. A thickness of the hole blocking layer is, for example, one molecular layer to 2 nm. In the case of AlN, one molecular layer is about 0.26 nm.

The electron blocking layer 13 is located on the active layer 12. The electron blocking layer 13 has a two-layer structure in which a first electron blocking layer and a second electron blocking layer are stacked in this order from the active layer 12 side. The electron blocking layer 13 prevents electrons injected from the n-side electrode 16 from going beyond the active layer 12 and diffusing toward the composition graded layer 14.

The electron blocking layer 13 does not necessarily have a two-layer structure, and may have only the first electron blocking layer.

The first electron blocking layer is made of AlGaN or AIN having an Al composition ratio higher than that of a barrier layer of the active layer 12, and the Al composition is, for example, 90% to 100%. The first electron blocking layer may be doped with a p-type impurity or may be non-doped. The p-type impurity is, for example, Mg. In the case of Mg-doped, a Mg concentration is, for example, 3×10²⁰ cm⁻³ or less. A thickness of the first electron blocking layer is, for example, 1 nm to 10 nm.

The second electron blocking layer is made of AlGaN having an Al composition lower than that of the first electron blocking layer, and the Al composition is, for example, 80% to 99%. A difference in Al composition from the composition graded layer 14 is adjusted by providing the second electron blocking layer. Resistance is increased in a case where only AlN is used as the first electron blocking layer, and when the first electron blocking layer is thinned, electron blocking performance is lowered. Therefore, the second electron blocking layer is provided to achieve both low resistance and an electron blocking function. The second electron blocking layer may be doped with a p-type impurity or may be non-doped. In the case of Mg-doped, a Mg concentration is, for example, 3×10²⁰ cm⁻³ or less. A thickness of the second electron blocking layer is, for example, 1 nm to 10 nm.

The composition graded layer 14 is located on the electron blocking layer 13. The composition graded layer 14 has a two-layer structure in which a first composition graded layer and a second composition graded layer are stacked in this order from the electron blocking layer 13 side.

The composition graded layer 14 is a p-type layer formed by a method called polarization doping. That is, the composition graded layer 14 is a layer in which an Al composition changes in a thickness direction, and is set such that the Al composition is reduced as a distance from the electron blocking layer 13 increases. It is difficult to increase a hole concentration in AlGaN having a high Al composition when doped with Mg, but the hole concentration can be improved by polarization doping, and the efficiency of hole injection into the active layer 12 can be increased. Since the polarization doping does not require doping with Mg, crystallinity can be improved.

When the Al composition of the composition graded layer 14 is set as described above, polarization due to strain of crystal occurs continuously in the thickness direction in the composition graded layer 14. Holes are generated in the composition graded layer 14 so as to cancel out fixed charges due to the polarization. The generated holes are distributed in the composition graded layer 14. Therefore, the holes are widely distributed in the thickness direction from the electron blocking layer 13 side in the composition graded layer 14, and the composition graded layer 14 becomes a p-type as a whole. In a p-type region, a hole concentration is 1×10¹⁶ cm⁻³ to 1×10²⁰ cm⁻³, and the hole concentration is reduced as a distance from the electron blocking layer 13 increases. A reason why the number of holes is reduced in the vicinity of an interface between the p-type contact layer 15 and the composition graded layer 14 is that a band is bent as the Fermi level tries to match due to p-type heterojunction.

A maximum value of an Al composition of the first composition graded layer (an Al composition at an interface between the first composition graded layer and the electron blocking layer 13) is preferably a value that is 1% to 20% lower than the Al composition of the electron blocking layer 13. The hole concentration can be further increased by polarization due to strain. For example, the maximum value of the Al composition is 65% to 95%.

A minimum value of the Al composition of the first composition graded layer (an Al composition at an interface between the first graded layer and the second composition graded layer) is preferably set to a value that is 3% to 30% lower than the maximum value of the Al composition of the first composition graded layer. The hole concentration can be further increased by polarization due to strain. In addition, an Al composition having band energy that does not absorb an emission wavelength is preferable.

A reduction rate of the Al composition of the first composition graded layer is preferably 0.1%/nm to 0.3%/nm. In such a range, the hole concentration of the first composition graded layer can be further increased. The reduction rate of the Al composition may be constant, that is, may change linearly, or may not be constant.

The first composition graded layer is non-doped. Alternatively, the first composition graded layer may be Mg-doped. Further improvement in the hole concentration can be expected due to a p-type impurity. In this case, the Mg concentration is, for example, 1×10²⁰ cm⁻³ or less. On the other hand, from the viewpoint of preventing a change in series resistance due to a change in the thickness of the first composition graded layer, the Mg concentration is preferably as low as possible, and the first composition graded layer is preferably non-doped.

The second composition graded layer is a layer having a Mg concentration higher than that of the first composition graded layer, and an Al composition of the second composition graded layer is the same as that of the first composition graded layer. The second composition graded layer is a layer having an Al composition that changes in a thickness direction, and is set such that the Al composition is reduced as a distance from the electron blocking layer 13 increases. The second composition graded layer can be well connected to the p-type contact layer 15 by doping the second composition graded layer with Mg.

A difference between a maximum value of the Al composition of the second composition graded layer (an Al composition at an interface between the second composition graded layer and the first composition graded layer) and a minimum value of the AI composition of the first composition graded layer is 0% to 5%, and the maximum value of the AI composition of the second composition graded layer is preferably the same as the minimum value of the Al composition of the first composition graded layer. That is, the Al composition is preferably continuous from the first composition graded layer to the second composition graded layer.

A minimum value of the Al composition of the second composition graded layer (an Al composition at an interface between the second composition graded layer and the p-type contact layer 15) is preferably a value that is 3% to 30% lower than the maximum value of the Al composition of the second composition graded layer.

A reduction rate of the Al composition of the second composition graded layer is in the same range as the reduction rate of the Al composition of the first composition graded layer. The reduction rate of the Al composition of the second composition graded layer may be the same as the reduction rate of the Al composition of the first composition graded layer.

A Mg concentration of the second composition graded layer is freely set as long as the Mg concentration of the second composition graded layer is higher than the Mg concentration of the first composition graded layer, and the Mg concentration of the second composition graded layer is preferably 3×10²⁰ cm⁻³ or less. This is to prevent series resistance.

In Embodiment 1, the Al composition of the composition graded layer 14 is continuously reduced. Alternatively, the Al composition may be reduced stepwise. It is preferable that a region where the Al composition is constant is as small as possible.

A ratio of the thickness of the first composition graded layer in the composition graded layer 14 is preferably 0.4 to 0.7. Within this range, good contact between the composition graded layer 14 and the p-type contact layer 15 can be achieved while sufficiently improving the hole concentration by polarization doping. The ratio is more preferably 0.4 to 0.6.

The composition graded layer 14 does not necessarily have a two-layer structure including the first composition graded layer and the second composition graded layer, and may have only the first composition graded layer. The composition graded layer 14 may have a structure of three or more layers having different change rates of the Al composition, different Mg concentrations, and the like.

A ratio of the thickness of the composition graded layer 14 to a total film thickness of the electron blocking layer 13, the composition graded layer 14, and the p-type contact layer 15 is preferably 50% or more and 90% or less. Within this range, a function of a p-type layer can be sufficiently improved.

Instead of the composition graded layer 14, a layer made of Mg-doped p-type AlGaN may be provided. In this case, a Mg concentration is, for example, 1×10¹⁷ cm⁻³ to 1×10¹⁹ cm⁻³. An Al composition is, for example, 40% to 80%.

The p-type contact layer 15 is located on the composition graded layer 14. The p-type contact layer 15 is made of Mg-doped p-GaN. The p-type contact layer 15 may be made of p-AlGaN having an Al composition lower than the minimum Al composition of the composition graded layer 14, and the Al composition is, for example, 50% or less.

For example, a thickness of the p-type contact layer 15 is preferably one molecular layer or more and 50 nm or less. GaN absorbs ultraviolet light emitted from the active layer 12, but can transmit ultraviolet light when the p-type contact layer 15 is sufficiently thinned. Therefore, a large decrease in external quantum efficiency can be avoided. The thickness is preferably 1 nm or more and 10 nm or less. A Mg concentration of the p-type contact layer 15 is, for example, 1×10²⁰ cm⁻³ to 1×10²² cm⁻³.

The p-type contact layer 15 may include a plurality of layers having different Al compositions or Mg concentrations. In the case of a plurality of layers, an uppermost layer in contact with the p-side electrode 17 is preferably made of p-GaN or AlGaN having a low Al composition. This is to reduce contact resistance with the p-side electrode 17.

A groove having a depth reaching the n-type layer 11 is provided in a partial region of a surface of the p-type contact layer 15. This groove is for provided for exposing the n-type layer 11 so that the n-side electrode 16 can be provided.

The n-side electrode 16 is provided on the n-type layer 11 exposed at a bottom surface of the groove. A material of the n-side electrode 16 is Ti/Al, V/Al, or the like. Here, A/B refers to that A and B are stacked in order from the n-type layer 11 side.

The p-side electrode 17 is provided on the p-type contact layer. The p-side electrode 17 is a reflective electrode that increases light extraction efficiency by reflecting ultraviolet light emitted from the active layer 12 toward the substrate 10. The p-side electrode 17 is made of Mg and is in contact with the p-type contact layer 15. Mg has high reflectivity for ultraviolet light, particularly in the UVC band, and enables good contact with a p-type group III nitride semiconductor. Therefore, by using Mg as the p-side electrode 17, reflectivity in the UVC band can be increased while maintaining good contact with the p-type contact layer 15.

A thickness of the p-side electrode 17 is preferably set such that the reflectivity of ultraviolet light with an emission wavelength is 50% or more. Here, the reflectivity is reflectivity when ultraviolet light is input perpendicularly to a main surface of the p-side electrode 17. The reflectivity is more preferably 70% or more, and is furthermore preferably 80% or more.

The thickness of the p-side electrode 17 is preferably 40 nm or more. When the thickness is 40 nm or more, reflectivity equal to or higher than reflectivity in a case where Ni/Mg is used as the p-side electrode 17 can be obtained. The thickness is more preferably 80 nm or more. When the thickness is 80 nm or more, reflectivity equal to or higher than reflectivity of Al can be obtained. The thickness is furthermore preferably 90 nm or more. An upper limit of the thickness of the p-side electrode 17 is not particularly limited, but when the thickness exceeds 80 nm, the reflectivity gradually becomes saturated, and a formation time and material costs increase. Therefore, the thickness is preferably 200 nm or less. The thickness is more preferably 160 nm or less.

Instead of Mg, the p-side electrode 17 may be made of a Mg alloy containing Mg as a main component. For example, a Mg—Al alloy, a Mg—Pt alloy, a Mg—Ni alloy, a Mg—Ni—Au alloy, or the like can be used. A ratio of Mg contained in an alloy is preferably 70 at % or more in order to increase reflectivity.

A protective layer made of Ti may be further provided on the p-side electrode 17 in a contact manner. The protective layer is a layer for protecting the p-side electrode 17 from a chemical solution in a step after the p-side electrode 17 is formed and protecting the p-side electrode 17 from being oxidized. TiN, Ni, Pt, Au, or the like can be used for the protective layer in addition to Ti. A thickness of the protective layer may be large enough to achieve the above object, and is, for example, 20 nm to 100 nm. The protective layer may be formed to cover not only an upper surface but also a side surface of the p-side electrode 17.

As described above, according to the light emitting element in Embodiment 1, since the p-side electrode 17 is made of Mg or a Mg alloy and is in contact with the p-type contact layer 15, contact resistance of the p-side electrode 17 with respect to the p-type contact layer 15 can be reduced, and reflectivity of ultraviolet light with an emission wavelength can be increased.

### 2. Manufacturing Method of Light Emitting Element

Next, a manufacturing method of the light emitting element according to Embodiment 1 will be described with reference to the drawings.

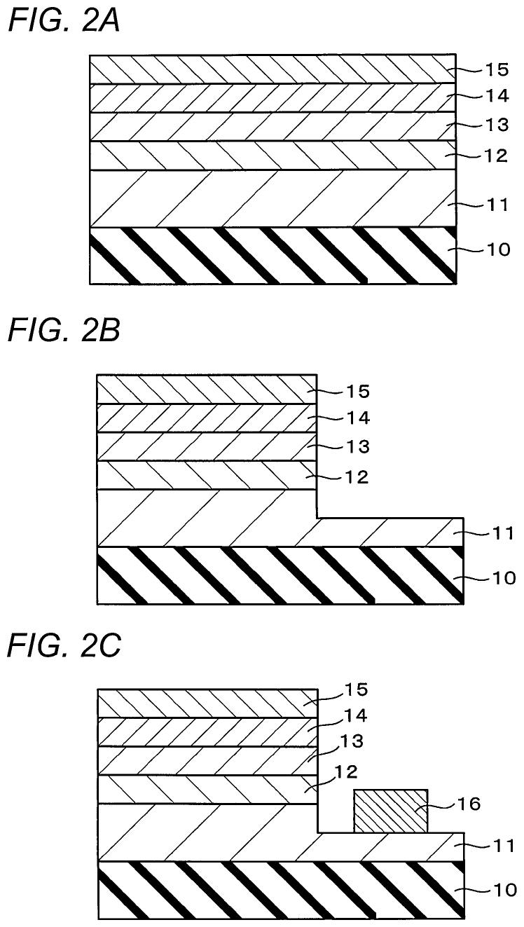

First, the n-type layer 11, the active layer 12, the electron blocking layer 13, the composition graded layer 14, and the p-type contact layer 15 are stacked in order on the substrate 10 via a buffer layer using a MOCVD method (see FIG. 2A).

Next, a predetermined region of the p-type contact layer 15 is dry-etched until reaching the n-type layer 11 to form a groove (see FIG. 2B).

Next, the n-side electrode 16 is formed, by sputtering or vapor deposition, on the n-type layer 11 exposed at the bottom surface of the groove (see FIG. 2C).

Next, annealing is performed at a temperature of 500° C. to 650° C. for 1 minutes to 10 minutes in an atmosphere containing oxygen. The atmosphere containing oxygen is, for example, an atmosphere in which oxygen is mixed with an inert gas such as nitrogen, and an oxygen concentration is, for example, 0.1 vol % to 1 vol %. The annealing is preferably performed at reduced pressure, for example, at 1×10² Pa to 1×10⁴ Pa. The annealing temperature is preferably 550° C. to 650° C.

By performing annealing in the atmosphere containing oxygen, not only contact resistance of the n-side electrode 16 can be reduced, but also Mg activation processing of the p-type contact layer 15 can be performed at the same time. Accordingly, resistance of the p-type contact layer 15 can be reduced, and contact resistance of the n-side electrode 16 with respect to the n-type layer 11 can be reduced at the same time. In this manner, the number of times of annealing is reduced by making the annealing common and performing the annealing at the same time. As a result of reducing the number of times of annealing, deterioration of electrical features of the light emitting element can be prevented.

Mg activation processing of the p-type contact layer 15 and contact resistance reduction of the n-side electrode 16 may be performed separately. For example, the Mg activation processing and the contact resistance reduction may be performed separately by changing a temperature, changing an atmosphere, and the like. However, it is preferable to make the Mg activation processing and the contact resistance reduction common and perform the Mg activation processing and the contact resistance reduction at the same time as in the embodiment from the viewpoint of a thermal damage to an element. When the Mg activation processing and the contact resistance reduction are performed separately, annealing for the contact resistance reduction of the n-side electrode 16 may be performed in an atmosphere not containing oxygen. When the Mg activation processing and the contact resistance reduction are performed separately, for example, formation of the p-type contact layer 15, annealing for Mg activation, formation of the n-side electrode 16, and annealing for n-contact are performed in order.

Next, the p-side electrode 17 is formed on the p-type contact layer 15 by sputtering or vapor deposition. Here, the p-side electrode 17 is formed to have a thickness at which the p-side electrode 17 functions as a reflective electrode. Specifically, the thickness of the p-side electrode 17 is set such that reflectivity of ultraviolet light with an emission wavelength is 50% or more. In particular, the thickness of the p-side electrode 17 may be 40 nm or more, and preferably 80 nm or more.

Next, annealing is performed in a nitrogen atmosphere at a temperature of 150° C. to 400° C. for 30 seconds or more and 12 minutes or less. The light emitting element according to Embodiment 1 is manufactured by the above steps. The annealing atmosphere is not limited to nitrogen, and may be an inert gas atmosphere. For example, a rare gas such as argon may be used, or a mixed gas of nitrogen and a rare gas may be used. The annealing may be performed at normal pressure, or may be performed at reduced pressure. When the annealing is performed at reduced pressure, the pressure is, for example, 1×10² Pa to 1×10⁴ Pa.

By performing the annealing after the formation of the p-side electrode 17, a forward voltage Vf of the light emitting element according to Embodiment 1 can be reduced as compared with a forward voltage Vf before annealing. Although a reason for such a reduction is not clear, it is considered that adhesiveness between the p-type contact layer 15 and the p-side electrode 17 is improved.

The annealing temperature is more preferably 200° C. or more and 350° C. or less. Within this range, the Vf can be further reduced as compared with the Vf before annealing, and reflectivity of the p-side electrode 17 can also be increased as compared of reflectivity before the annealing. The temperature is more preferably 250° C. or more and 330° C. or less.

The annealing time is more preferably 2 minutes or more and 8 minutes or less. Within this range, the Vf can be further reduced as compared with the Vf before annealing, and reflectivity of the p-side electrode 17 can also be increased as compared of reflectivity before the annealing. The annealing time is more preferably 3 minutes or more and 7 minutes or less.

As described above, according to the manufacturing method of the light emitting element in Embodiment 1, since the annealing is performed under a predetermined condition after the formation of the p-side electrode 17, the Vf of the light emitting element can be reduced, and reflectivity can be further increased.

### 3. Experimental Examples According to Embodiment

Next, various experimental examples according to Embodiment 1 will be described.

### Experiment 1

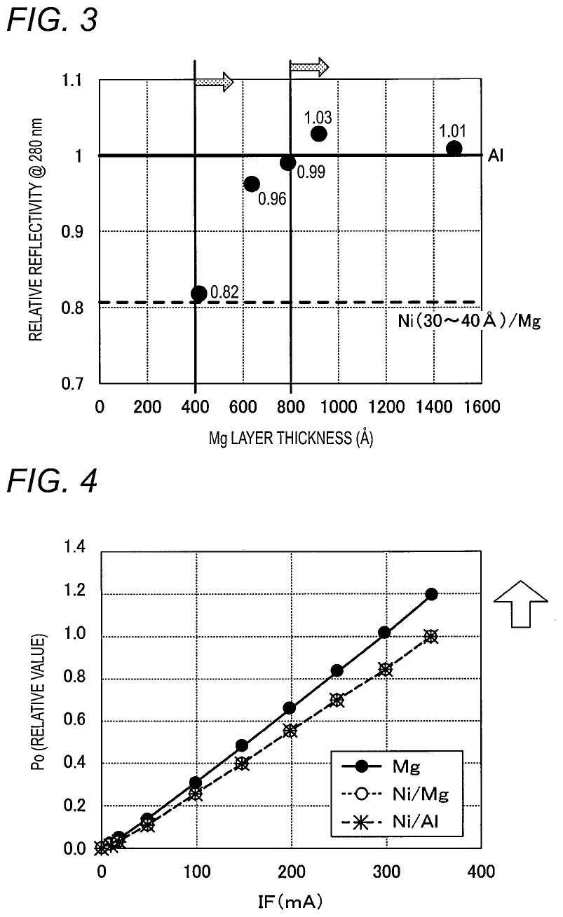

A Mg layer was formed on a sapphire substrate, and ultraviolet light having a wavelength of 280 nm was perpendicularly emitted from a back surface (a surface opposite to the Mg layer) of the sapphire substrate to measure reflectivity. FIG. 3 is a graph showing a relationship between a thickness of the Mg layer and relative reflectivity. The relative reflectivity is a normalized relative value assuming that reflectivity when an Al layer having a thickness of 100 nm is provided instead of the Mg layer is 1. The relative reflectivity was also measured when Ni/Mg was provided instead of the Mg layer for comparison. A thickness of Ni/Mg is 3 nm to 4 nm, and a thickness of Mg is 130 nm.

As shown in FIG. 3, as the thickness of the Mg layer increased, the relative reflectivity increased. When the thickness of the Mg layer was 40 nm or more, the relative reflectivity of the Mg layer was higher than the relative reflectivity 0.81 of Ni/Mg. When the thickness of the Mg layer was 80 nm or more, the reflectivity was higher than reflectivity of the Al layer.

### Experiment 2

The light emitting element according to Embodiment 1 in which each layer has the following configuration was manufactured (hereinafter, referred to as a light emitting element according to Example 1). A layer configuration of the light emitting element is as follows in order from the p-side electrode 17 toward the substrate 10. The Al composition of the composition graded layer 14 was continuously reduced from 78% to 72%.
p-side electrode 17: Mg
p-type contact layer 15: Mg-doped GaN, thickness: 10 nm
composition graded layer 14: Mg-doped AlGaN, thickness: 25.5 nm
composition graded layer 14: non-doped AlGaN, thickness: 25.5 nm
electron blocking layer 13: Mg-doped AlGaN, Al composition: 97%, thickness: 8.8 nm
electron blocking layer 13: Mg-doped AIN, thickness: 8 nm
barrier layer of active layer 12: Si-doped AlGaN, Al composition: 68%, thickness: 2.5 nm
well layer of active layer 12: non-doped AlGaN, Al composition: 46%, thickness: 1.7 nm
barrier layer of active layer 12: Si-doped AlGaN, Al composition: 68%, thickness: 9.4 nm
hole blocking layer: non-doped AlN, thickness: 0.5 nm
well layer of SL layer: non-doped AlGaN, Al composition: 46%, thickness: 0.5 nm
barrier layer of SL layer: Si-doped AlGaN, Al composition: 68%, thickness: 50 nm
n-type layer 11: Si-doped AlGaN, Al composition: 73%, thickness: 35 nm
n-type layer 11: Si-doped AlGaN, Al composition: 73%, thickness: 150 nm
n contact layer: Si-doped AlGaN, Al composition: 73%, thickness: 1200 nm
re-growth layer: AlN containing Ga, Al composition: 98%, thickness: 200 nm
AlN template: AlN, thickness: 2900 nm
Sapphire: thickness 430 μm

For comparison, a light emitting element in which the p-side electrode 17 was changed to Ni/Al (hereinafter, referred to as a light emitting element according to Comparative Example 1) and a light emitting element in which the p-side electrode 17 was changed from a Mg layer to Ni/Mg (hereinafter, referred to as a light emitting element according to Comparative Example 2) were manufactured. Light outputs Po, external quantum efficiency EQE, I-V features, and power conversion efficiency WPE of the light emitting elements according to Example 1 and Comparative Examples 1 and 2 were measured.

FIG. 4 is a graph showing current dependence of light outputs Po of the light emitting elements according to Example 1 and Comparative Examples 1 and 2. The light output Po is a normalized relative value assuming that the Po in Comparative Example 1 at a current of 350 mA is 1. As shown in FIG. 4, it was found that the light output Po of the light emitting element according to Example 1 was higher than the light outputs Po of the light emitting elements according to Comparative Examples 1 and 2. At a current of 350 mA, the light output Po of the light emitting element according to Example 1 was 19.3% higher than that of the light emitting element according to Comparative Example 1. The light outputs Po in Comparative Examples 1 and 2 were approximately the same.

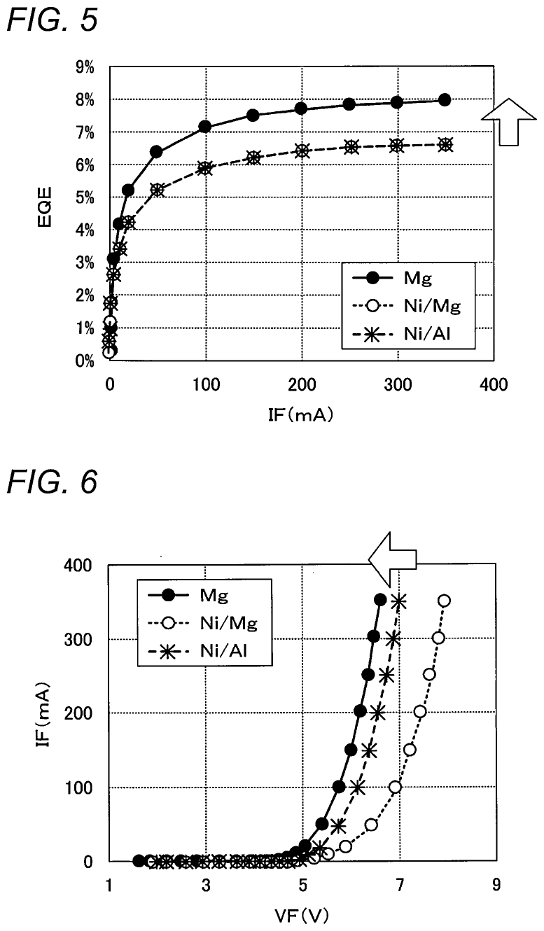

FIG. 5 is a graph showing current dependence of the external quantum efficiency EQE of the light emitting elements according to Example 1 and Comparative Examples 1 and 2. As shown in FIG. 5, it was found that the external quantum efficiency EQE of the light emitting element according to Example 1 was higher than the external quantum efficiency EQE of the light emitting elements according to Comparative Examples 1 and 2. At a current of 350 mA, the external quantum efficiency EQE of the light emitting element according to Example 1 was 19.7% higher than that of the light emitting element according to Comparative Example 1. The external quantum efficiency EQE in Comparative Examples 1 and 2 was approximately the same.

From FIGS. 4 and 5, it is considered that since reflectivity of ultraviolet light was increased by using Mg as the p-side electrode 17, light extraction was improved and the light output Po and the external quantum efficiency EQE were increased.

FIG. 6 is a graph showing the I-V features of the light emitting elements according to Example 1 and Comparative Examples 1 and 2. As shown in FIG. 6, it was found that Vf of the light emitting element according to Example 1 was lower than Vf of the light emitting elements according to Comparative Examples 1 and 2. At a current of 350 mA, the Vf of the light emitting element according to Example 1 was 5.1% lower than that of the light emitting element according to Comparative Example 1. A reason why the Vf was reduced is considered to be that Mg had better adhesiveness to the p-type contact layer 15 than Ni/Al and Ni/Mg, and contact resistance was reduced.

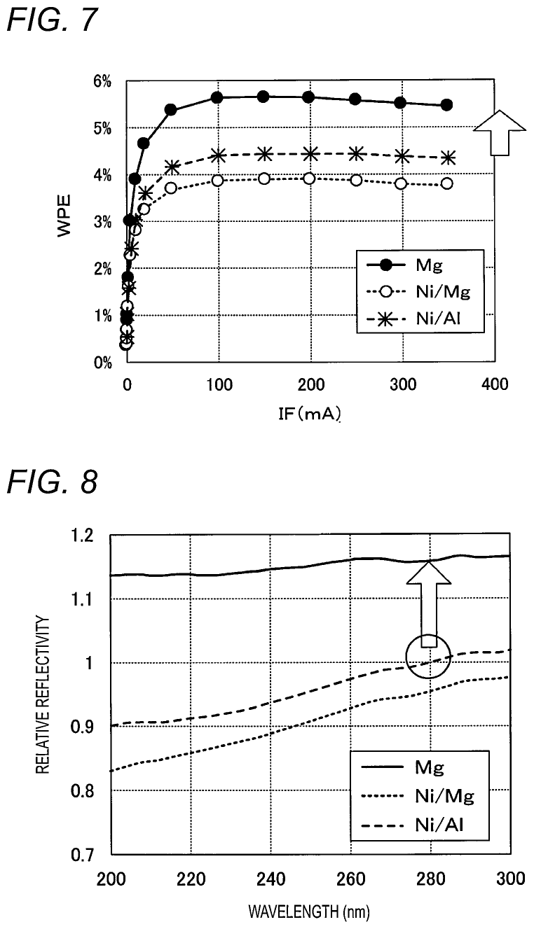

FIG. 7 is a graph showing the power conversion efficiency WPE of the light emitting elements according to Example 1 and Comparative Examples 1 and 2. As shown in FIG. 7, the power conversion efficiency WPE of the light emitting element according to Example 1 was higher than the power conversion efficiency WPE of the light emitting elements according to Comparative Examples 1 and 2. At a current of 350 mA, the power conversion efficiency WPE of the light emitting element according to Example 1 was 25.6% higher than that of the light emitting element according to Comparative Example 1.

### Experiment 3

A Mg layer was formed on a sapphire substrate, and ultraviolet light was perpendicularly emitted from a back surface (a surface opposite to the Mg layer) of the sapphire substrate to measure reflectivity. A wavelength of the ultraviolet light was changed in a range of 200 nm to 300 nm. A thickness of the Mg layer was 130 nm. FIG. 8 is a graph showing a relationship between a wavelength of ultraviolet light and relative reflectivity. For comparison, relative reflectivity when Ni/Al was provided instead of the Mg layer and relative reflectivity when Ni/Mg was provided instead of the Mg layer were also measured. Of Ni/Al, a thickness of Ni was 3 nm to 4 nm, and a thickness of Al was 130 nm. Of Ni/Mg, a thickness of Ni was 3 nm to 4 nm, and a thickness of Mg was 130 nm. The relative reflectivity is a normalized relative value assuming that reflectivity at a wavelength of 280 nm in the case of Ni/Al is 1.

As shown in FIG. 8, Mg had higher reflectivity than Ni/Al and Ni/Mg at any wavelength in a range of 200 nm to 280 nm.

### Experiment 4

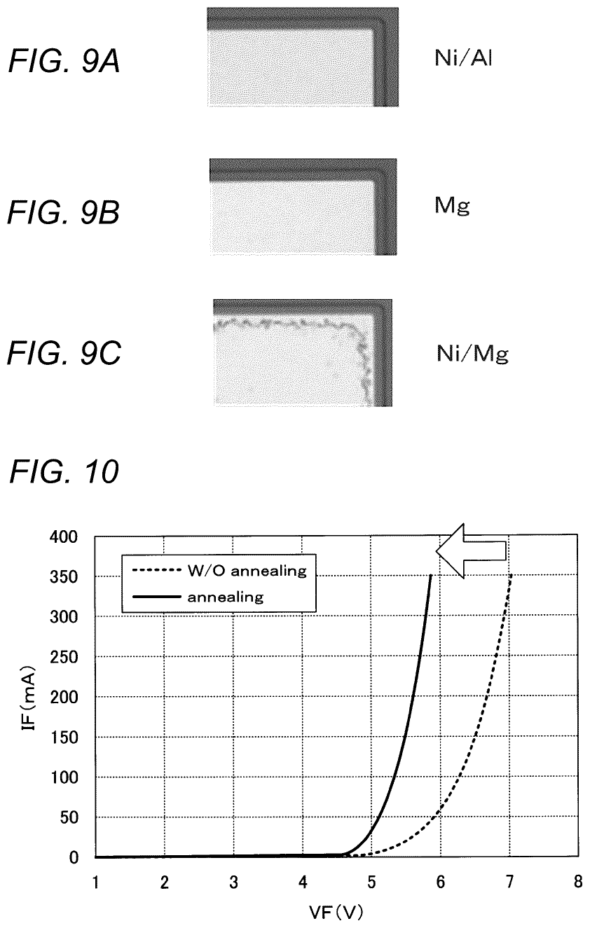

With respect to the light emitting elements according to Example 1 and Comparative Examples 1 and 2, micrographs of the p-side electrode 17 were captured, and adhesiveness of the p-side electrode 17 was confirmed. FIGS. 9A to 9C are views showing micrographs of the p-side electrode 17, FIG. 9A shows a micrograph in the case of Ni/Al, FIG. 9B shows a micrograph in the case of Mg, and FIG. 9C shows a micrograph in the case of Ni/Mg. As shown in FIG. 9C, it was confirmed that peeling occurred at an end portion of an element in the case of Ni/Mg. On the other hand, as shown in FIGS. 9A and 9B, no peeling was observed in the case of Ni/Al or Mg. As described above, it was found that adhesiveness to the p-type contact layer 15 in a case where Mg was directly formed on the p-type contact layer 15 was better than a case where Mg was formed on the p-type contact layer 15 via Ni. Therefore, it is considered that a reason why Vf in the case where the p-side electrode 17 is made of Mg is lower than that in the case of Ni/Mg is that the adhesiveness is good.

### Experiment 5

I-V features and emission spectra of the light emitting element according to Example 1 were measured when annealing was performed and when annealing was not performed after the p-side electrode 17 was formed. The annealing was performed in a nitrogen atmosphere at 300° C. for 6 minutes.

FIG. 10 is a graph showing the I-V features before and after annealing. As shown in FIG. 10, it was found that Vf was reduced by performing annealing. At a current of 350 mA, Vf was reduced by 1.2 V by performing annealing.

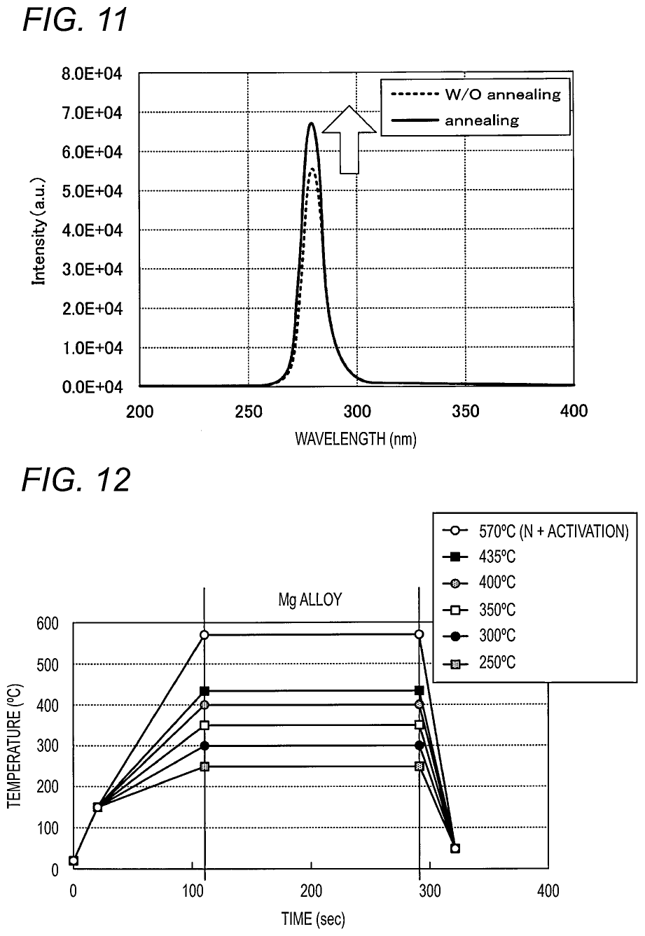

FIG. 11 is a graph showing emission spectra before and after annealing. As shown in FIG. 11, it was found that an output at 280 nm which is a peak of an emission wavelength was increased.

Although a reason why the Vf is reduced and the light output is increased by performing annealing is not clear, the reason may be that adhesiveness between the p-type contact layer 15 and Mg is increased. Of course, other factors are not excluded.

### Experiment 6

For the light emitting element according to Example 1, annealing was performed after the p-side electrode 17 was formed, and a relationship between an annealing temperature and a Vf reduction amount was studied. Mg/Ti was formed on a sapphire substrate, and then annealing was performed to study a relationship between an annealing temperature and a reflectivity change amount. The annealing was performed in a nitrogen atmosphere for 3 minutes, and a temperature was changed from 250° C. to 570° C. FIG. 12 is a graph showing a change over time in the annealing temperature. As shown in FIG. 12, the temperature was increased to 150° C. after about 20 seconds from the start of heating, and then increased to each set temperature after 90 seconds. The set temperature was maintained for 3 minutes, and then heating was stopped and the temperature was lowered.

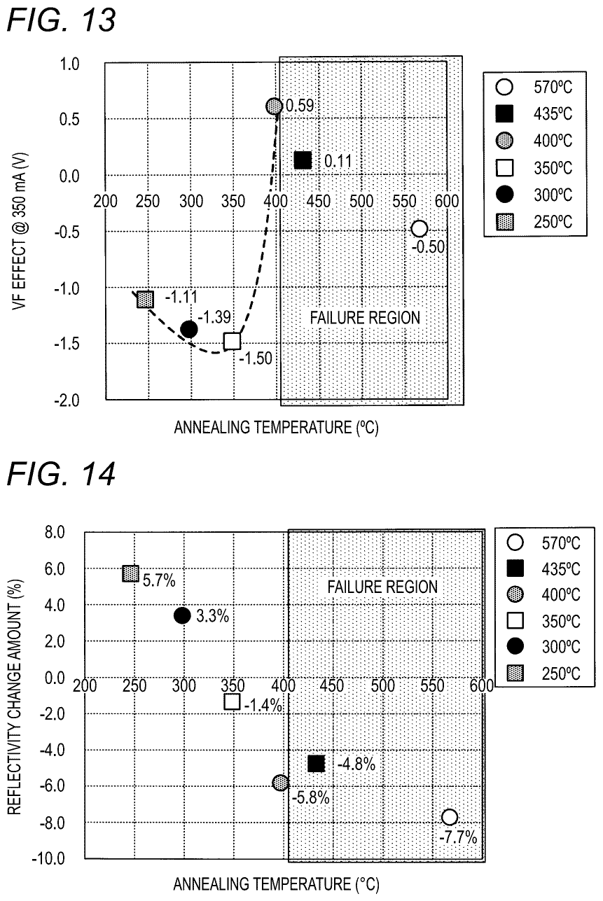

FIG. 13 is a graph showing a relationship between an annealing temperature and a Vf reduction amount. The Vf reduction amount indicates how much Vf after annealing changed with respect to Vf before annealing at 350 mA. As shown in FIG. 13, it was found that Vf after annealing was lower than Vf before annealing when the annealing temperature was lower than 400° C. On the other hand, it was found that Vf after annealing was higher than Vf before annealing at 400° C. When the temperature exceeded 400° C., a failure occurred in a light emitting element. From the above, it was found that the annealing temperature needs to be 400° C. or less, and it is sufficient that the annealing temperature is less than 400° C. in order to reduce Vf.

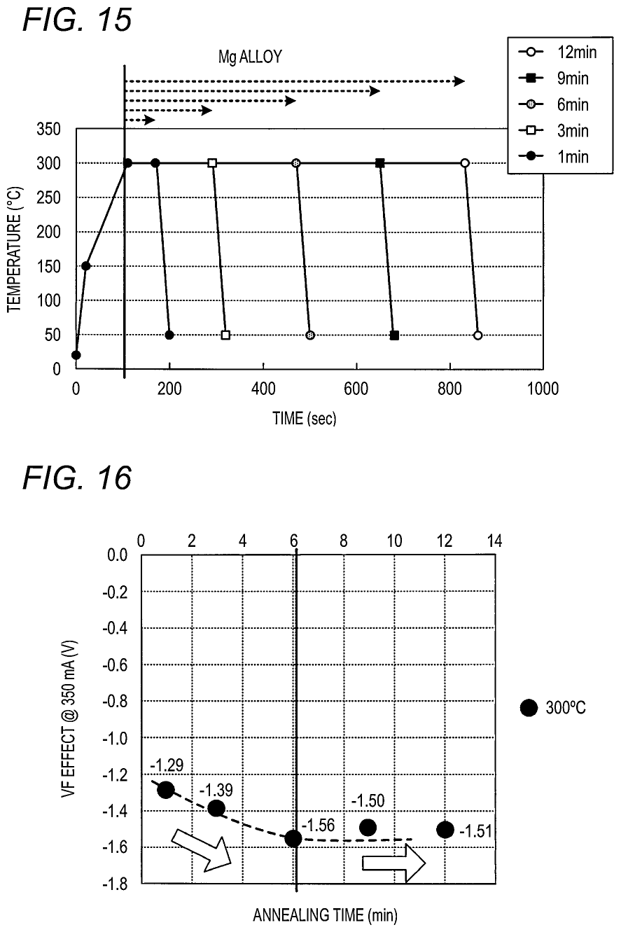

FIG. 14 is a graph showing a relationship between an annealing temperature and a reflectivity change amount of Mg/Ti. The reflectivity change amount indicates how much reflectivity after annealing changed with respect to reflectivity before annealing. Of Mg/Ti, a thickness of Mg was 130 nm, and a thickness of Ti was 52 nm. The other conditions were the same as those in Experiment 1. As shown in FIG. 14, it was found that when the annealing temperature was 300° C. or less, reflectivity after annealing was higher than reflectivity before annealing. On the other hand, when the annealing temperature was 350° C. or higher, reflectivity after annealing was lower than reflectivity before annealing. From the above, it was found that the annealing temperature needs to be less than 350° C. in order to increase reflectivity.

### Experiment 7

For the light emitting element according to Example 1, annealing was performed after the p-side electrode 17 was formed, and a relationship between an annealing time and a Vf reduction amount was studied. Mg/Ti was formed on a sapphire substrate, and then annealing was performed to study a relationship between an annealing time and a reflectivity change amount. The annealing was performed in a nitrogen atmosphere at a temperature of 300° C. The annealing time was changed from 1 minute to 12 minutes. FIG. 15 is a graph showing a change over time in an annealing temperature. As shown in FIG. 15, the temperature was increased to 150° C. after about 20 seconds from the start of heating, and then increased to 300° C. after 90 seconds. The temperature was maintained at 300° C. for each set time, and then heating was stopped and the temperature was lowered.

FIG. 16 is a graph showing a relationship between an annealing time and a Vf reduction amount. The Vf reduction amount indicates how much Vf after annealing changed with respect to Vf before annealing at 350 mA. As shown in FIG. 16, it was found that Vf after annealing was lower than Vf before annealing at any annealing time of 1 minutes to 12 minutes. In addition, it was found that, before the annealing time of 6 minutes, the Vf reduction amount increased as the annealing time increased, but when the annealing time exceeded 6 minutes, the Vf reduction amount was saturated and became approximately constant. From the above, it was found that the annealing time needs to be 1 minute or more in order to reduce Vf. In addition, it is estimated that there is a Vf reduction effect when the annealing time is in a range of 30 seconds or more and less than 1 minute.

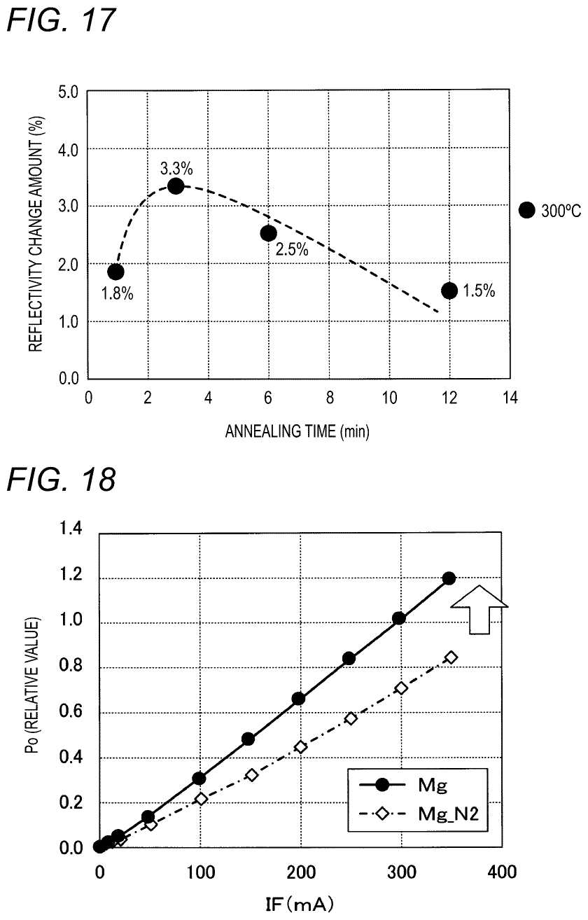

FIG. 17 is a graph showing a relationship between an annealing time and a reflectivity change amount of Mg/Ti. The reflectivity change amount indicates how much reflectivity after annealing changed with respect to reflectivity before annealing. Of Mg/Ti, a thickness of Mg was 130 nm, and a thickness of Ti was 52 nm. The other conditions were the same as those in Experiment 1. As shown in FIG. 17, it was found that reflectivity after annealing was higher than reflectivity before annealing at any annealing time of 1 minutes to 12 minutes. From the above, it was found that the annealing time needs to be 1 minute or more in order to increase reflectivity.

### Experiment 8

For the light emitting element according to Example 1, in annealing after the n-side electrode 16 was formed and before the p-side electrode 17 was formed, light outputs Po and Vf were compared between a case of a nitrogen atmosphere and a case of a mixed gas atmosphere containing nitrogen and oxygen. An annealing temperature was 570° C., and an annealing time was 4 minutes. An oxygen concentration of the mixed gas was 0.3 vol %.

FIG. 18 is a graph showing a relationship between a light output Po and a current of the light emitting element according to Example 1. As shown in FIG. 18, the light output Po in a case where the annealing atmosphere is a mixed gas of nitrogen and oxygen was higher than that in a case where the annealing atmosphere is only nitrogen.

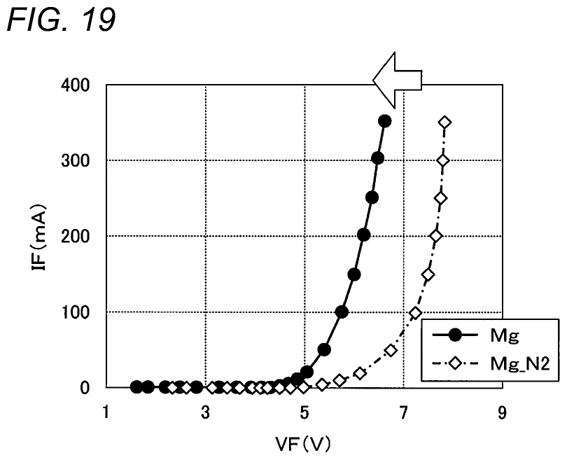

FIG. 19 is a graph showing I-V features of the light emitting element according to Example 1. As shown in FIG. 19, Vf in a case where the annealing atmosphere is the mixed gas of nitrogen and oxygen was lower than that in a case where the annealing atmosphere is only nitrogen.

It was found from FIGS. 18 and 19 that by performing annealing in a mixed gas containing oxygen before the p-side electrode 17 is formed, low contact of the n-side electrode 16 and activation of the p-type contact layer 15 can be achieved at the same time, and the light output Po can be increased and the Vf can be reduced.

### REFERENCE SIGNS LIST

10: substrate
11: n-type layer
12: active layer
13: electron blocking layer
14: composition graded layer
15: p-type contact layer
16: n-side electrode
17: p-side electrode

What is claimed is:

1. A flip-chip type light emitting element of ultraviolet light emission, the light emitting element comprising:
a p-type layer comprising a p-type group III nitride semiconductor; and
a p-side electrode serving as a reflective electrode provided over the p-type layer, wherein
the p-side electrode comprises Mg or an alloy containing Mg as a main component and is in contact with the p-type layer.

2. The light emitting element according to claim 1, wherein
a thickness of the p-side electrode is set such that reflectivity at an emission wavelength is 50% or more.

3. The light emitting element according to claim 1, wherein
a thickness of the p-side electrode is 40 nm or more.

4. The light emitting element according to claim 2, wherein
a thickness of the p-side electrode is 40 nm or more.

5. The light emitting element according to claim 3, wherein
the thickness of the p-side electrode is 80 nm or more.

6. The light emitting element according to claim 4, wherein
the thickness of the p-side electrode is 80 nm or more.

7. The light emitting element according to claim 1, further comprising:
a protective layer that is provided on and is in contact with the p-side electrode and comprises Ti, TiN, or Ni.

8. The light emitting element according to claim 1, wherein
an emission wavelength of the light emitting element is 210 nm to 280 nm.

9. A manufacturing method of a flip-chip type light emitting element of ultraviolet light emission, the light emitting element including a p-type layer containing a p-type group III nitride semiconductor and a p-side electrode serving as a reflective electrode provided over the p-type layer, the manufacturing method comprising:
forming the p-side electrode so that the p-side electrode is provided on and is in contact with the p-type layer and contains Mg or an alloy containing Mg as a main component; and
performing annealing in an inert gas atmosphere at a temperature of 150° C. or more and 400° C. or less for 30 seconds or more and 12 minutes or less after the forming of the p-side electrode.

10. The manufacturing method of a light emitting element according to claim 9, wherein
the temperature in the annealing is 200° C. or more and 350° C. or less.

11. The manufacturing method of a light emitting element according to claim 9, wherein
the annealing is performed for 2 minutes or more and 8 minutes or less.

12. The manufacturing method of a light emitting element according to claim 10, wherein
the annealing is performed for 2 minutes or more and 8 minutes or less.

13. The manufacturing method of a light emitting element according to claim 9, wherein
the forming of the p-side electrode is performed so that a thickness of the p-side electrode is 40 nm or more.

14. The manufacturing method of a light emitting element according to claim 13, wherein
the forming of the p-side electrode is performed so that the thickness of the p-side electrode is 80 nm or more.

15. The manufacturing method of a light emitting element according to claim 9, further comprising:
forming a protective layer so that the protective layer is provided on and is in contact with the p-side electrode and contains Ti, TiN or Ni.

16. The manufacturing method of a light emitting element according to claim 9, wherein
the light emitting element has an emission wavelength of 210 nm to 280 nm.
